(19) United States
(12) Patent Application Publication
(10) Pub. No.: US 2026/0324162 A1
(43) Pub. Date: Oct. 15, 2026

(54) DISPLAY SUBSTRATE AND METHOD FOR MANUFACTURING THE SAME, DISPLAY PANEL AND DISPLAY DEVICE

(71) Applicants: Beijing BOE Technology Development Co., Ltd., Beijing (CN); BOE TECHNOLOGY GROUP CO., LTD., Beijing (CN)

(72) Inventors: Mingxing WANG, Beijing (CN); Huajie YAN, Beijing (CN); Qian SUN, Beijing (CN); Wei LI, Beijing (CN); Zhiqiang JIAO, Beijing (CN); Guangcai YUAN, Beijing (CN); Ying ZHOU, Beijing (CN); Wenqi LIU, Beijing (CN); Xinyu LI, Beijing (CN); Keyi ZHANG, Beijing (CN); Qian JIN, Beijing (CN); Zhongyuan SUN, Beijing (CN); Che AN, Beijing (CN)

(21) Appl. No.: 18/853,110

(22) PCT Filed: Nov. 30, 2023
(86) PCT No.: PCT/CN2023/135392

§ 371 Date: Sep. 30, 2024

(51) Int. Cl. H10H 29/80; H10H 29/01

(52) U.S. Cl. CPC H10H 29/8325; H10H 29/032

(57) ABSTRACT

A display substrate is provided, including: a base substrate including a display area and a peripheral area at least partially surrounding the display area; and pixel units in the display area in an array along first and second directions intersecting with each other. At least one pixel unit includes: a reflective bonding structure including a first electrode, a first reflective electrode and a first bonding portion sequentially arranged on the base substrate; and an LED light-emitting unit including a second bonding portion, an LED epitaxial layer and a second electrode sequentially arranged on a side of the first bonding portion away from the base substrate. An orthographic projection of the second bonding portion on the base substrate is within that of the first bonding portion on the base substrate, and the first bonding portion and the second bonding portion include the same material.

### CROSS-REFERENCE TO RELATED APPLICATION(S)

This application is a Section 371 National Stage Application of International Application No. PCT/CN2023/135392, filed Nov. 30, 2023, entitled “DISPLAY SUBSTRATE AND METHOD FOR MANUFACTURING THE SAME, DISPLAY PANEL AND DISPLAY DEVICE”, incorporated herein by reference in its entirety.

### TECHNICAL FIELD

The present disclosure relates to the field of display technology, and in particular to a display substrate and a method for manufacturing the same, a display panel and a display device.

### BACKGROUND

With the explosion of metaverse, augmented reality (AR) display technology has ushered in an opportunity for rapid development. An AR display system mainly includes a micro-display unit for displaying and an optical system for synthesizing an image and projecting it to the human eye. Currently, micro display units used for AR display include micro inorganic light-emitting diode (abbreviated as Micro-LED) displays.

However, there are still a lot of problems restricting the development of Micro-LEDs, including technical bottlenecks such as the uniformity of an LED epitaxial layer, miniaturization, the degradation of light efficiency during the miniaturization process, and high-precision bonding. How to achieve high-luminance and high-resolution display in the miniaturization of LEDs is one of the important research topics for R&D personnel.

The above information disclosed in this section is only for understanding the background of the inventive concept of the present disclosure and therefore the above information may contain information that does not constitute the prior art.

### SUMMARY

In an aspect, a display substrate is provided. The display substrate includes: a base substrate, including a display area and a peripheral area, the peripheral area at least partially surrounding the display area; and a plurality of pixel units arranged in the display area of the base substrate, the plurality of pixel units being arranged in an array in the display area along a first direction and a second direction, at least one of the pixel units including a reflective bonding structure and an LED light-emitting unit, and the first direction intersecting with the second direction, where the reflective bonding structure includes: a first electrode arranged on the base substrate; a first reflective electrode arranged on a side of the first electrode away from the base substrate; and a first bonding portion arranged on a side of the first reflective electrode away from the base substrate; and where the LED light-emitting unit includes: a second bonding portion arranged on a side of the first bonding portion away from the base substrate; an LED epitaxial layer arranged on a side of the second bonding portion away from the base substrate; and a second electrode arranged on a side of the LED epitaxial layer away from the base substrate, where an orthographic projection of the second bonding portion on the base substrate is located within an orthographic projection of the first bonding portion on the base substrate; and where the first bonding portion and the second bonding portion include a same material.

According to some exemplary embodiments, the first bonding portion and the second bonding portion include the same material selected from ITO or IZO.

According to some exemplary embodiments, the first bonding portion includes a first slope angle ranging from 70° to 85°; and/or, the second bonding portion includes a second slope angle ranging from 70° to 85°.

According to some exemplary embodiments, a material of the first electrode is one of ITO or IZO; and/or, a material of the first reflective electrode is silver.

According to some exemplary embodiments, the display substrate further includes a partition between pixel units adjacent to each other, where the partition covers at least a part of a surface of the LED epitaxial layer away from the base substrate, a sidewall of the reflective bonding structure, and a sidewall of the LED light-emitting unit.

According to some exemplary embodiments, the partition has a first thickness in a third direction, the third direction being perpendicular to each of the first direction and the second direction; the reflective bonding structure has a second thickness in the third direction; the second bonding portion has a third thickness in the third direction; and the LED epitaxial layer has a fourth thickness in the third direction, where the first thickness is greater than a sum of the second thickness, the third thickness and the fourth thickness.

According to some exemplary embodiments, the LED epitaxial layer includes: a second semiconductor layer arranged on the side of the second bonding portion away from the base substrate; a quantum well layer arranged on a side of the second semiconductor layer away from the base substrate; and a first semiconductor layer arranged on a side of the quantum well layer away from the base substrate; and the partition includes a hole, exposing at least a part of a surface of the first semiconductor layer away from the base substrate.

According to some exemplary embodiments, the second electrode includes a main body portion and a second conductive connection portion, an orthographic projection of the second conductive connection portion on the base substrate coincides with an orthographic projection of the partition on the base substrate, and second electrodes of two pixel units adjacent to each other are electrically connected via the second conductive connection portion, where the main body portion has a fifth thickness in a third direction, and the second conductive connection portion has a sixth thickness in the third direction, the fifth thickness being greater than the sixth thickness.

According to some exemplary embodiments, the display substrate further includes a metal conductive layer arranged on a side of the second electrode away from the base substrate, where an orthographic projection of the metal conductive layer on the base substrate is located within the orthographic projection of the second conductive connection portion on the base substrate; and where the metal conductive layer includes a plurality of first conductive sub-portions arranged along the first direction and a plurality of second conductive sub-portions arranged along the second direction, and the plurality of first conductive sub-portions and the plurality of second conductive sub-portions are electrically connected to each other.

According to some exemplary embodiments, the metal conductive layer includes: a first metal conductive sub-layer arranged on the side of the second electrode away from the base substrate; a second metal conductive sub-layer arranged on a side of the first metal conductive sub-layer away from the base substrate; and a third metal conductive sub-layer arranged on a side of the second metal conductive sub-layer away from the base substrate, where an orthographic projection of the second metal conductive sub-layer on the base substrate is located within an orthographic projection of the first metal conductive sub-layer on the base substrate; and where an orthographic projection of the third metal conductive sub-layer on the base substrate is located within the orthographic projection of the second metal conductive sub-layer on the base substrate.

According to some exemplary embodiments, the display substrate further includes a prism portion arranged on a side of the second electrode away from the base substrate, where an orthographic projection of the prism portion on the base substrate at least partially overlaps with an orthographic projection of the LED epitaxial layer on the base substrate.

According to some exemplary embodiments, the display substrate further includes a first conductive transfer portion and a second conductive transfer portion arranged in the peripheral area, the first conductive transfer portion being electrically connected to the second conductive transfer portion, where the first conductive transition portion includes a first conductive transfer sub-portion, a second conductive transfer sub-portion, a third conductive transfer sub-portion, and a fourth conductive transfer sub-portion, where the first conductive transfer sub-portion and the first electrode are arranged in a same layer; the second conductive transfer sub-portion and the first reflective electrode are arranged in a same layer; the third conductive transfer sub-portion and the first bonding portion are arranged in a same layer; and the fourth conductive transfer sub-portion and the second bonding portion are arranged in a same layer; and where the second conductive transfer sub-portion includes a fifth conductive transfer sub-portion and a sixth conductive transfer sub-portion, where the fifth conductive transfer sub-portion and the second electrode are arranged in a same layer; and the sixth conductive transfer sub-portion and the metal conductive layer are arranged in a same layer.

According to some exemplary embodiments, the display substrate further includes an inorganic encapsulation layer arranged between the LED light-emitting unit and the prism portion.

According to some exemplary embodiments, the inorganic encapsulation layer includes n inorganic encapsulation sub-layers that are alternately arranged, where two inorganic encapsulation sub-layers adjacent to each other among the n inorganic encapsulation sub-layers have different refractive indexes, n being a positive integer greater than or equal to 3.

According to some exemplary embodiments, a refractive index of a material of an inorganic encapsulation sub-layer of an even number among the n inorganic encapsulation sub-layers is greater than or equal to 1.85.

According to some exemplary embodiments, the prism portion includes a top surface away from the base substrate, the top surface being a cambered surface.

According to some exemplary embodiments, a radius of curvature of the cambered surface is greater than or equal to 2 um

According to some exemplary embodiments, the display substrate further includes a third via hole between inorganic encapsulation layers of LED light-emitting units adjacent to each other; and a reflective layer arranged in the third via hole, where the reflective layer is configured to reflect at least part of light emitted from a side surface by the LED light-emitting unit.

According to some exemplary embodiments, the reflective layer includes m inorganic reflective sub-layers that are alternately arranged, and a difference between refractive indexes of two inorganic reflective sub-layers adjacent to each other among the m inorganic reflective sub-layers is greater than or equal to 0.4, m being a positive integer greater than or equal to 2.

According to some exemplary embodiments, the reflective layer includes a metal reflective layer or a black adhesive reflective layer.

In another aspect, a display panel is provided. The display panel includes the any one of the display substrate in any one of the embodiments mentioned above.

In yet another aspect, a display device is provided. The display device includes any one of the display substrates mentioned above, or the display panel mentioned above.

In yet another aspect, a method for manufacturing a display substrate is provided. The method includes: sequentially depositing a first electrode material layer, a first reflective electrode material layer and a first bonding material layer on a base substrate; performing a patterning process on the first electrode material layer, the first reflective electrode material layer and the first bonding material layer to form reflective bonding structures arranged in an array, where the reflective bonding structure includes a first electrode arranged in the first electrode material layer, a first reflective electrode arranged in the first reflective electrode material layer, and a first bonding portion arranged in the first bonding material layer; epitaxially growing a whole layer of semiconductor buffer material layer, a whole layer of first semiconductor material layer, a whole layer of quantum well material layer and a whole layer of second semiconductor material layer on a wafer, so as to form an LED epitaxial layer; depositing a whole layer of second bonding material layer on the second semiconductor material layer; performing a bonding process on the whole layer of second bonding material layer and the reflective bonding structures arranged in the array; after the bonding process is completed, peeling off the wafer, removing the semiconductor buffer material layer, and thinning the first semiconductor material layer, so as to form a thinned LED epitaxial layer; performing a patterning process on the thinned LED epitaxial layer and the second bonding material layer, so as to form a first via hole and a plurality of LED light-emitting portions arranged in an array corresponding to the reflective bonding structures; forming an insulation layer on a side of the LED epitaxial layer away from the base substrate, and performing a patterning process on the insulation layer, so as to form a second via hole exposing the LED epitaxial layer and a partition between LED light-emitting units adjacent to each other; and forming a second electrode layer on a side of the insulation layer away from the base substrate.

According to some exemplary embodiments, the method further includes: alternately forming a first inorganic encapsulation sub-layer and a second inorganic encapsulation sub-layer on a side of the LED light-emitting units away from the base substrate, so as to form an inorganic encapsulation layer including n inorganic encapsulation sub-layers, n being a positive integer greater than or equal to 3; forming a whole layer of first prism layer on a side of the inorganic encapsulation layer away from the base substrate; forming a whole layer of photoresist layer on a side of the first prism layer away from the base substrate, and performing a patterning process on the photoresist layer, so as to form photoresist retention portions respectively corresponding to the LED light-emitting units; performing a thermal reflowing process on the photoresist retention portions to form photoresist prism portions; and simultaneously etching the photoresist prism portions and the first prism layer until the photoresist prism portions are removed, so as to form prism portions arranged in an array and respectively corresponding to the LED light emitting units.

### BRIEF DESCRIPTION OF THE DRAWINGS

Features and advantages of the present disclosure will become more apparent by describing exemplary embodiments of the present disclosure with reference to the accompanying drawings in detail.

FIG. 1 shows a schematic plan view of a display substrate according to some exemplary embodiments of the present disclosure;

FIG. 2 shows a schematic cross-sectional view of the display substrate in FIG. 1 along line AA′, according to some exemplary embodiments of the present disclosure;

FIG. 3 shows a partial enlarged schematic diagram of the display substrate in FIG. 2 in dashed area S, according to some exemplary embodiments of the present disclosure;

FIG. 4 shows a schematic cross-sectional view of the display substrate in FIG. 1 along line AA′, according to some other exemplary embodiments of the present disclosure;

FIG. 5 shows a partial schematic plan view of a metal conductive layer in FIG. 4;

FIG. 6 shows a schematic cross-sectional view of the display substrate in FIG. 1 along line AA′, according to some other exemplary embodiments of the present disclosure;

FIG. 7 shows a schematic cross-sectional view of the display substrate along line BB′ in FIG. 1, according to some exemplary embodiments of the present disclosure;

FIG. 8 shows a schematic cross-sectional view of the display substrate along line CC′ in FIG. 1, according to some exemplary embodiments of the present disclosure;

FIG. 9A shows a schematic structural diagram of an inorganic encapsulation layer in a display substrate according to some exemplary embodiments of the present disclosure;

FIG. 9B shows a schematic structural diagram of an inorganic encapsulation layer in a display substrate according to some other exemplary embodiments of the present disclosure;

FIG. 10 shows a schematic diagram of a relationship between a gas ratio and a refractive index of an inorganic encapsulation layer according to some exemplary embodiments of the present disclosure;

FIG. 11 shows a comparative schematic diagram of light intensities of a display substrate with different prism diameters at different viewing angles, according to some exemplary embodiments of the present disclosure;

FIG. 12 shows a schematic diagram of crosstalk between adjacent pixels of a display substrate at different viewing angles, according to some exemplary embodiments of the present disclosure;

FIG. 13 shows a schematic structural diagram of a reflective layer of a display substrate according to some exemplary embodiments of the present disclosure;

FIG. 14A shows a schematic structural diagram of a reflective layer of a display substrate according to some other exemplary embodiments of the present disclosure; FIG. 14B shows a schematic diagram of density distribution of photons of a display substrate without a reflective layer according to some exemplary embodiments of the present disclosure; FIG. 14C shows a schematic diagram of density distribution of photons of a display substrate provided with the reflective layer in FIG. 14A;

FIG. 15 shows a schematic structural diagram of a display panel according to some exemplary embodiments of the present disclosure;

FIG. 16 shows a schematic structural diagram of a display device according to some exemplary embodiments of the present disclosure;

FIG. 17 shows a flow chart of a method for manufacturing a display substrate according to some exemplary embodiments of the present disclosure; FIG. 18 to FIG. 26 show partial structural schematic diagrams of the display substrate at different stages of the manufacturing process of FIG. 17, respectively; and

FIG. 27 shows a flow chart of forming an inorganic encapsulation layer and a prism portion according to some exemplary embodiments of the present disclosure; FIG. 28 to FIG. 32 show partial structural schematic diagrams of the display substrate at different stages of the manufacturing process of FIG. 27, respectively.

It should be noted that, for the sake of clarity, in the accompanying drawings used to describe the embodiments of the present disclosure, sizes of layers, structures or regions may be enlarged or reduced, that is, these drawings are not drawn according to actual scales.

### DETAILED DESCRIPTION OF EMBODIMENTS

In order to make the objectives, technical solution and advantages of embodiments of the present disclosure clearer, the technical solution(s) of the embodiments of the present disclosure will be clearly and completely described below in conjunction with the drawings of the embodiments of the present disclosure. Obviously, the described embodiments are only part of the embodiments of the present disclosure, rather than all the embodiments. Based on the described embodiments of the present disclosure, all other embodiments obtained by those of ordinary skill in the art without inventive labor are within the scope of protection of the present disclosure.

It should be noted that, for sake of clarity and/or description, sizes and relative sizes of elements may be enlarged in the drawings. Thus, the sizes and relative sizes of the respective elements are not necessarily limited to the sizes and relative sizes shown in the drawings. In the specification and drawings, the same or similar reference numerals indicate the same or similar components.

Unless otherwise defined, technical or scientific terms used in the present disclosure should have the common meanings understood by one of ordinary skill in the art. The terms “first”, “second” and the like used in the present disclosure do not indicate any order, quantity or importance, but are only used to distinguish different components. The words “include”, “comprise” or the like mean that the elements or objects preceding the word include the elements or objects listed after the word and their equivalents, but do not exclude other elements or objects.

In the present disclosure, unless otherwise specifically stated, directional terms such as “upper”, “lower”, “left”, “right”, “inside”, “outside”, etc. are used to indicate the orientation or positional relationship based on the drawings, and are only for ease of description of the present disclosure, but do not indicate or imply that the device, element or component referred to have to have a specific orientation, or be constructed or operated in a specific orientation. It should be understood that when the absolute positions of the described objects change, the relative positional relationships they represent may also change accordingly. Therefore, these directional terms should not be construed as limiting the present disclosure.

It should be noted that, in the present disclosure, the expression “same layer” refers to a layer structure formed by forming a film layer used for forming a specific pattern through the same film forming process, and then patterning the film layer through a single patterning process using the same mask. Depending on the specific pattern, the patterning process may include a plurality of exposure, development or etching processes, and the specific pattern in the formed layer structure may be continuous or discontinuous. That is, a plurality of elements, components, structures and/or parts located in the “same layer” are composed of the same material and are formed by using the same patterning process. Generally, the plurality of elements, components, structures and/or parts located in the “same layer” have substantially the same thickness.

Those skilled in the art should understand that, in the present disclosure, unless otherwise specified, the expression “height” or “thickness” refers to a dimension of a surface of each film layer arranged perpendicular to the display substrate. That is, a dimension along the light output direction of the display substrate, or a dimension along the normal direction of the display device.

In the present disclosure, the directional expressions “first direction” and “second direction” are used to describe different directions along the pixel unit, for example, longitudinal and transverse directions of the pixel unit, or row and column directions in which the sub-pixels are arranged. It should be understood that such representations are merely exemplary descriptions and are not limitations to the present disclosure.

In the present disclosure, the inorganic light-emitting diode refers to a light-emitting element made of inorganic materials, and LED represents an inorganic light-emitting element different from OLED. Specifically, the inorganic light-emitting element may include a mini light-emitting diode (abbreviated as Mini LED) and a micro light-emitting diode (abbreviated as Micro LED). Here, a micro light-emitting diode (i.e. Micro LED) refers to an ultra-small light-emitting diode with a die size less than 100 microns, and a mini light-emitting diode (i.e. Mini LED) refers to a small light-emitting diode with a die size between that of a Micro LED and that of a traditional LED. For example, the die size of the Mini LED may be between 50 microns and 400 microns.

LEDs may be used to manufacture a mini LED display and a Micro LED display due to their high refresh rate, high luminance, active light-emitting mode, and miniaturization. Micro LEDs have an excellent luminance, a high light-emitting efficiency, a low energy consumption, a high response speed, a high contrast, an ultra-high resolution, and an ultra-high color saturation, thus they are considered to be an ideal display technology. Micro LEDs have most of the advantages of LEDs, and further has characteristics of a small size, easy disassembly, and a high flexibility. Therefore, Micro LEDs are the most promising optical engine in AR products. Although Micro LEDs have incomparable advantages, there are still a lot of problems restricting the development thereof, mainly including uniformity of an epitaxial layer, a miniaturization process, a decreased light efficiency caused by a miniaturization process, a decreased efficiency under a low current, a high-precision bonding technology, an ultra-high resolution Micro LED driving technology, colorization, a high cost, etc. Among them, how to achieve high-precision bonding between high-density LED chips and driving circuits in the base substrate during the miniaturization of LEDs is an urgent problem to be solved in the development of high-resolution Micro LED display.

In the embodiments of the present disclosure, a display substrate is provided. The display substrate includes: a base substrate, including a display area and a peripheral area, the peripheral area at least partially surrounding the display area; and a plurality of pixel units arranged in the display area of the base substrate, the plurality of pixel units being arranged in an array in the display area along a first direction and a second direction, at least one of the pixel units including a reflective bonding structure and an LED light-emitting unit, and the first direction intersecting with the second direction. The reflective bonding structure includes: a first electrode arranged on the base substrate; a first reflective electrode arranged on a side of the first electrode away from the base substrate; and a first bonding portion arranged on a side of the first reflective electrode away from the base substrate. The LED light-emitting unit includes: a second bonding portion arranged on a side of the first bonding portion away from the base substrate; an LED epitaxial layer arranged on a side of the second bonding portion away from the base substrate; and a second electrode arranged on a side of the LED epitaxial layer away from the base substrate. An orthographic projection of the second bonding portion on the base substrate is located within an orthographic projection of the first bonding portion on the base substrate, and the first bonding portion and the second bonding portion include the same material. By forming first bonding portions arranged in an array on the base substrate and forming a whole layer of second bonding material layer made of a material the same as the first bonding portions on the LED epitaxial layer, the bonding between the LED epitaxial layer and the base substrate may be achieved without alignment, so as to improve the success rate of bonding. Furthermore, after the bonding is completed, micro-array designs of the LED epitaxial layer and the second bonding material layer may be realized through a patterning process, so as to ensure that the orthographic projection of the second bonding portion on the base substrate is located within the orthographic projection of the first bonding portion on the base substrate, and the LED light-emitting units arranged in an array is formed, thereby realizing a high-resolution display design.

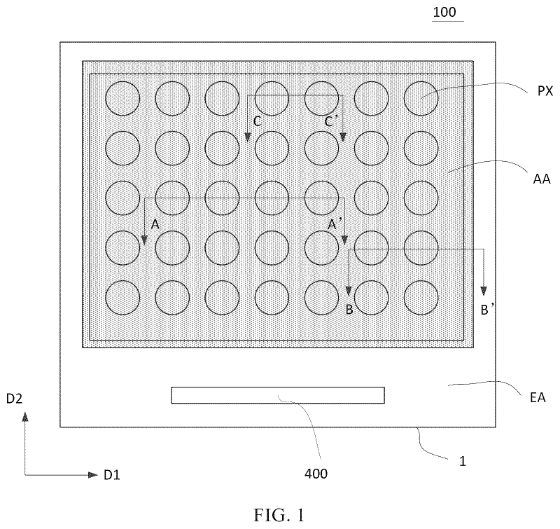

FIG. 1 shows a schematic plan view of a display substrate according to some exemplary embodiments of the present disclosure.

Referring to FIG. 1, a display substrate 100 includes: a base substrate 1 including a display area AA and a peripheral area EA, the peripheral area EA at least partially surrounding the display area AA; a plurality of pixel units PX arranged in the display area AA of the base substrate 1, the plurality of pixel units PX being arranged in an array in the display area AA along a first direction D1 and a second direction D2, and the first direction D1 intersecting with the second direction D2. The display substrate 100 further includes a bonding area 400 in the peripheral area EA, and the bonding area 400 may be used for an electrical connection between the display substrate and an external driving chip.

It should be noted that although in the embodiments of the present disclosure, the pixel unit PX in a shape of a circle is schematically showed in the drawings, in other embodiments, the pixel opening may also be in various shapes such as a rectangle, an ellipse, a square, or a triangle. In addition, the light-emitting units of different colors corresponding to different pixel units may be arranged in various manners known in the art, and the embodiments of the present disclosure do not impose any particular limitation to this.

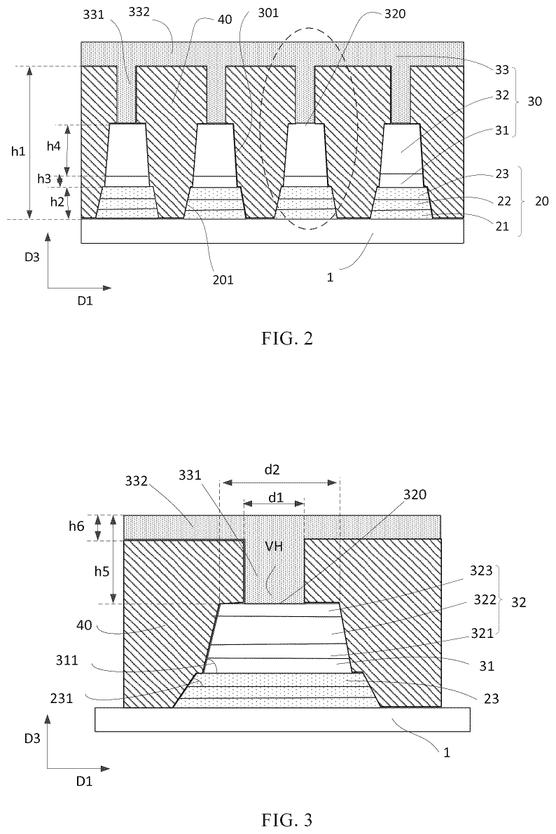

FIG. 2 shows a schematic cross-sectional view of the display substrate in FIG. 1 along line AA′, according to some exemplary embodiments of the present disclosure.

Exemplarily, referring to FIG. 2, at least one pixel unit PX includes a reflective bonding structure 20 and an LED light-emitting unit 30, and the LED light-emitting unit 30 may emit one of red light, green light, and blue light. The reflective bonding structure 20 includes: a first electrode 21 arranged on the base substrate 1; a first reflective electrode 22 arranged on a side of the first electrode 21 away from the base substrate 1; and a first bonding portion 23 arranged on a side of the first reflective electrode 22 away from the base substrate 1. The LED light-emitting unit 30 includes: a second bonding portion 31 arranged on a side of the first bonding portion 23 away from the base substrate 1; an LED epitaxial layer 32 arranged on a side of the second bonding portion 31 away from the base substrate; and a second electrode 33 arranged on a side of the LED epitaxial layer 32 away from the base substrate.

In this embodiment, the second bonding portion 31 and the first bonding portion 23 include the same material, which is conducive to improving the bonding strength between the second bonding portion 31 and the first bonding portion 23, so as to ensure that the LED light-emitting unit 30 is tightly bonded to the base substrate 1.

Exemplarily, a thickness of the first bonding portion 23 ranges from 10 nm to 500 nm, and a thickness of the second bonding portion 31 ranges from 50 nm to 500 nm. A surface roughness of the first bonding portion 23 and a surface roughness of the second bonding portion 31 are both less than 1 nm. For example, the surface roughness of the first bonding portion 23 and the surface roughness of the second bonding portion 31 are both less than 0.5 nm. By controlling the roughness, the bonding strength between the first bonding portion and the second bonding portion may be improved, thereby improving a reliability of the display substrate.

In some embodiments of the present disclosure, the base substrate 1 further includes a driving circuit (not shown) for driving the pixel unit. Not only may a physical bonding between the LED light-emitting unit and the base substrate be achieved through the first bonding portion and the second bonding portion, but also an electrical connection between the LED light-emitting unit and the driving circuit in the base substrate may be achieved by designing the first bonding portion and the second bonding portion to be made of a conductive material, thereby achieving drive and control of the LED light-emitting unit. For example, the first bonding portion 23 and the second bonding portion 31 include the same material selected from ITO or IZO.

In some embodiments of the present disclosure, the first electrode 21, the first reflective electrode 22 and the first bonding portion 23 in the reflective bonding structure 20 are electrically connected to each other. Exemplarily, the material of the first electrode 21 may be one of ITO and IZO, and the thickness of the first electrode 21 ranges from 10 nm to 500 nm; and/or the material of the first reflective electrode 22 may be silver, and the thickness of the first reflective electrode 22 ranges from 50 nm to 500 nm. By arranging the first reflective electrode between the LED light-emitting unit and the base substrate, it may be ensured that most of the light emitted by the LED light-emitting unit is emitted in a direction away from the base substrate, thereby improving a light extraction efficiency of the display substrate and achieving high-luminance display.

Exemplarily, in some embodiments of the present disclosure, with continued reference to FIG. 2, the display substrate 100 further includes a partition 40 between pixel units PX adjacent to each other, and the partition 40 covers at least a part of a surface 320 of the LED epitaxial layer 32 away from the base substrate, a sidewall 201 of the reflective bonding structure 20, and a sidewall 301 of the LED light-emitting unit. The partition 40 has a first thickness h1 in a third direction D3, and the third direction D3 is perpendicular to each of the first direction D1 and the second direction D2. The reflective bonding structure 20 has a second thickness h2 in the third direction D3. The second bonding portion 31 has a third thickness h3 in the third direction D3. The LED epitaxial layer 32 has a fourth thickness h4 in the third direction D3. In the embodiments of the present disclosure, the first thickness h1 is greater than a sum of the second thickness h2, the third thickness h3 and the fourth thickness h4. By arranging the partition between pixel units PX adjacent to each other, a leakage of electricity between the pixel units PX adjacent to each other may be reduced, thereby improving the display effect of the display substrate.

Exemplarily, a material of the partition may include SiO₂, SiN or SiON, or a stacked layer of any two or three of SiO2, SiN and SiON, or an organic insulation layer such as spin on glass (SOG), benzocyclobutene (BCB), etc.

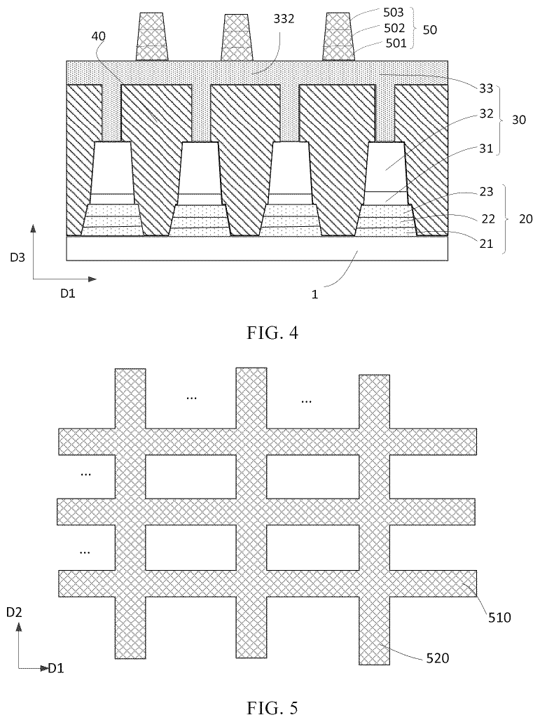

FIG. 3 shows a partial enlarged schematic diagram of the display substrate in FIG. 2 in dashed area S, according to some exemplary embodiments of the present disclosure.

Exemplarily, in some embodiments of the present disclosure, the first bonding portion 23 may be implemented as a regular trapezoidal structure by using a patterning process, where the first bonding portion 23 includes a first slope angle 231 in a range of 70° to 85°; and/or, the second bonding portion 31 may be implemented as a regular trapezoidal structure by using a patterning process, where the second bonding portion 31 includes a second slope angle 311 in a range of 70° to 85°. The first slope angle 231 may be greater than the second slope angle 311, for example, the first slope angle 231 is 85° and the second slope angle 311 is 70°. Or, the first slope angle 231 may be equal to the second slope angle 311, for example, the first slope angle 231 is 80° and the second slope angle 311 is 80°. Or, the first slope angle 231 may be smaller than the second slope angle 311, for example, the first slope angle 231 is 70° and the second slope angle 311 is 85°.

Exemplarily, with continued reference to FIG. 3, an orthographic projection of the second bonding portion 31 on the base substrate is located within an orthographic projection of the first bonding portion 23 on the base substrate. An orthographic projection of the LED epitaxial layer 32 on the base substrate is located within the orthographic projection of the second bonding portion 31 on the base substrate.

By configuring the orthographic projection of the second bonding portion 31 on the base substrate to be located within the orthographic projection of the first bonding portion 23 on the base substrate, the bonding strength between the second bonding portion 31 and the first bonding portion 23 may be improved. Furthermore, by configuring the first bonding portion 23 and the second bonding portion 31 to each have a large slope angle, it may be ensured that while a good bonding is formed between the first bonding portion 23 and the second bonding portion 31, a space occupied by the non-light-emitting portion may be reduced as much as possible, and a duty cycle of the light-emitting area may be increased, thereby facilitating high-resolution display.

Exemplarily, in some embodiments of the present disclosure, with continued reference to FIG. 3, the LED epitaxial layer 32 includes: a second semiconductor layer 321 arranged on the side of the second bonding portion 31 away from the base substrate 1; a quantum well layer 322 arranged on a side of the second semiconductor layer 321 away from the base substrate 1; and a first semiconductor layer 323 arranged on a side of the quantum well layer 322 away from the base substrate. The LED epitaxial layer 32 may emit one of blue light, red light or green light under an external electric field. For example, the first semiconductor layer 323 may include an n-GaN material, the quantum well layer 322 may include a plurality of pairs of quantum wells, for example, the quantum well layer 322 may include 1 to 25 pairs of quantum wells, and the second semiconductor layer 321 may include a p-GaN material, so that the LED epitaxial layer 32 may emit blue light when an electric field is applied.

Exemplarily, the partition 40 includes a hole VH, and the hole VH exposes at least a part of the surface 320 of the first semiconductor layer 323 away from the base substrate. With continued reference to FIG. 3, the hole VH has a first width d1 in the first direction, and the surface 320 of the first semiconductor layer 323 away from the base substrate has a second width d2 in the first direction, the first width d1 being smaller than the second width d2. For example, a difference between the second width d2 and the first width d1 is greater than or equal to 0.1 um, so that while the light-emitting area may be utilized as much as possible, an isolation effect of the partition may be ensured and the leakage of electricity between pixel units may be reduced, thereby improving the display effect of the display substrate.

Exemplarily, in some embodiments of the present disclosure, with reference to FIG. 2 and FIG. 3, the second electrode 33 includes a main body portion 331 and a second conductive connection portion 332, an orthographic projection of the second conductive connection portion 332 on the base substrate 1 coincides with an orthographic projection of the partition 40 on the base substrate, and the second electrodes 33 of two pixel units PX adjacent to each other are electrically connected through the second conductive connection portion 332. The main body portion 331 has a fifth thickness h5 in the third direction D3, and the second conductive connection portion 332 has a sixth thickness h6 in the third direction D3, the fifth thickness h5 being greater than the sixth thickness h6.

By configuring the electrical connection between the second electrodes of pixel units adjacent to each other, a common cathode design for more than one pixel unit may be realized, so that a wiring space may be saved, which is conducive to realizing the high-resolution display design.

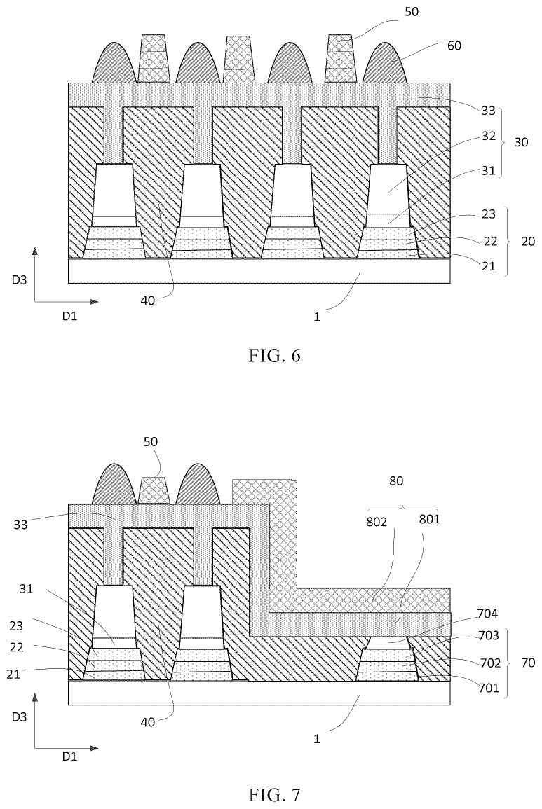

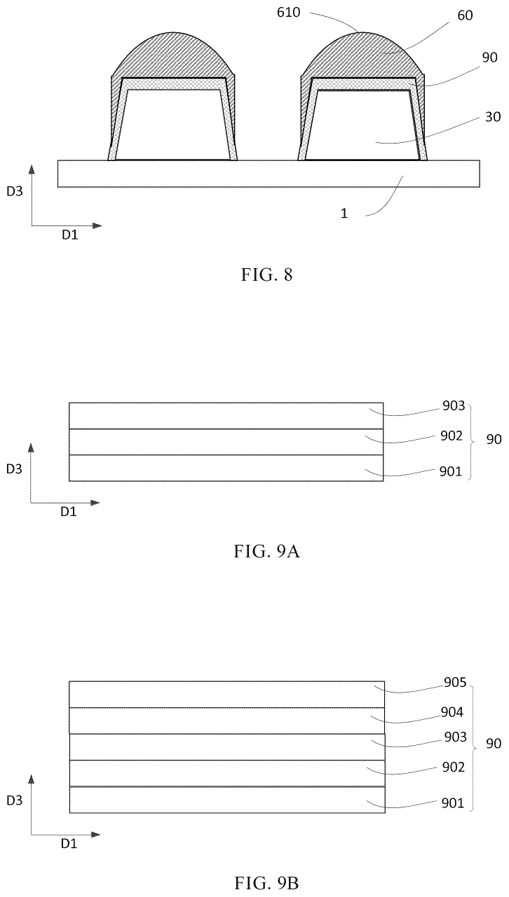

FIG. 4 shows a schematic cross-sectional view of the display substrate in FIG. 1 along line AA′, according to some other exemplary embodiments of the present disclosure. FIG. 5 shows a partial schematic plan view of a metal conductive layer in FIG. 4.

Exemplarily, in some embodiments of the present disclosure, with reference to FIG. 4 and FIG. 5, the display substrate 100 further includes a metal conductive layer 50 arranged on a side of the second electrode 33 away from the base substrate 1. An orthographic projection of the metal conductive layer 50 on the base substrate 1 is located within the orthographic projection of the second conductive connection portion 332 on the base substrate 1. The metal conductive layer 50 includes a plurality of first conductive sub-portions 510 extending along the first direction D1 and a plurality of second conductive sub-portions 520 extending along the second direction D2, and the plurality of first conductive sub-portions 510 and the plurality of second conductive sub-portions 520 are electrically connected to each other, thereby forming a mesh metal auxiliary electrode.

By arranging the metal conductive layer 50 above the second electrode 33 which is electrically connected to the metal conductive layer 50, it is possible to reduce the voltage drop of a control signal during transmission, thereby improving the uniformity of light emitted by the respective pixel units and improving the display effect of the display substrate. The orthographic projection of the metal conductive layer 50 on the base substrate 1 does not overlap with the orthographic projection of the LED light-emitting unit 30 on the base substrate 1, so that it may be ensured that the light-transmitting area of the pixel unit is as large as possible, which is conducive to achieving the high-resolution display.

Exemplarily, in some embodiments of the present disclosure, with continued reference to FIG. 4, the metal conductive layer 50 may include a plurality of stacked metal conductive sub-layers. For example, the metal conductive layer 50 includes: a first metal conductive sub-layer 501 arranged on the side of the second electrode 33 away from the base substrate 1; a second metal conductive sub-layer 502 arranged on a side of the first metal conductive sub-layer 501 away from the base substrate 1; and a third metal conductive sub-layer 503 arranged on a side of the second metal conductive sub-layer 502 away from the base substrate. An orthographic projection of the second metal conductive sub-layer 502 on the base substrate 1 is located within an orthographic projection of the first metal conductive sub-layer 501 on the base substrate 1, and an orthographic projection of the third metal conductive sub-layer 503 on the base substrate 1 is located within the orthographic projection of the second metal conductive sub-layer 502 on the base substrate 1. For example, a material of the first metal conductive sub-layer 501 is Ti, a material of the second metal conductive sub-layer 502 is Al, and a material of the third metal conductive sub-layer 503 is Ti. Each of the first metal conductive sub-layer 501, the second metal conductive sub-layer 502 and the third metal conductive sub-layer 503 may be formed using a sputtering coating process, which may bring a high production efficiency. In addition, the first metal conductive sub-layer 501, the second metal conductive sub-layer 502 and the third metal conductive sub-layer 503 may be patterned using a dry etching process, which may bring a high patterning precision and facilitate realizing the high-resolution display.

Exemplarily, the metal conductive layer 50 may also be reflective. By optimizing a thickness and an angle of the second metal conductive sub-layer 502, the light extraction efficiency of the display substrate may be improved.

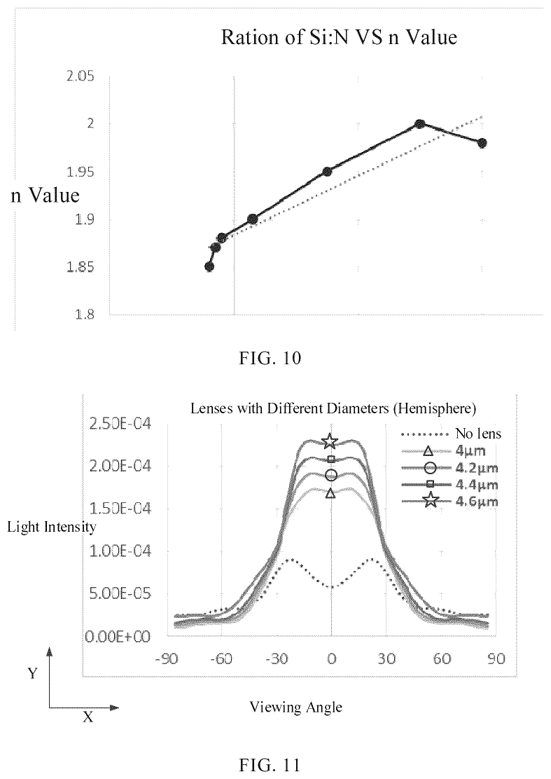

FIG. 6 shows a schematic cross-sectional view of the display substrate in FIG. 1 along line AA′, according to some other exemplary embodiments of the present disclosure.

Exemplarily, in some embodiments of the present disclosure, the display substrate 100 further includes a prism portion 60 arranged on the side of the second electrode 33 away from the base substrate 1. An orthographic projection of the prism portion 60 on the base substrate 1 at least partially overlaps with the orthographic projection of the LED epitaxial layer 32 on the base substrate 1.

Exemplarily, the prism portion 60 may include an organic material, such as photoresist, or may include an inorganic material, such as a combination of one or more of SiO₂, SiON or SiN.

By arranging the prism portion above the LED epitaxial layer, a probability of total reflection on the light output side may be reduced, thus the light-emitting efficiency of the display substrate may be improved, which is conducive to realizing the high-luminance display.

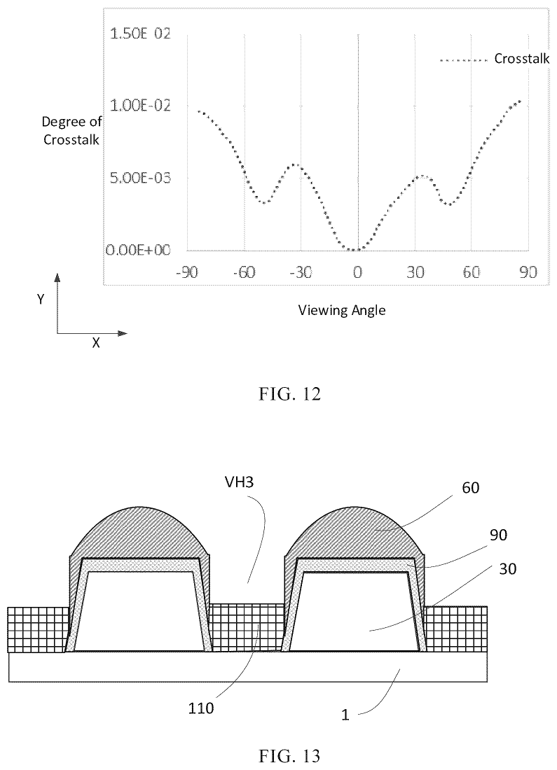

FIG. 7 shows a schematic cross-sectional view of the display substrate in FIG. 1 along line BB′, according to some exemplary embodiments of the present disclosure.

Exemplarily, in some embodiments of the present disclosure, the display substrate 100 further includes a first conductive transfer portion 70 and a second conductive transfer portion 80 in the peripheral area EA, and the first conductive transfer portion 70 is electrically connected to the second conductive transfer portion 80. The first conductive transfer portion 70 includes a first conductive transfer sub-portion 701, a second conductive transfer sub-portion 702, a third conductive transfer sub-portion 703, and a fourth conductive transfer sub-portion 704. For example, the first conductive transfer sub-portion 701 and the first electrode 21 are arranged in the same layer, the second conductive transfer sub-portion 702 and the first reflective electrode 22 are arranged in the same layer, the third conductive transfer sub-portion 703 and the first bonding portion 23 are arranged in the same layer, and the fourth conductive transfer sub-portion 704 and the second bonding portion 31 are arranged in the same layer. The first conductive transfer sub-portion 701, the second conductive transfer sub-portion 702, the third conductive transfer sub-portion 703 and the reflective bonding structure 20 may be formed in the same process step, and the fourth conductive transfer sub-portion 704 and the second bonding portion 31 may be formed in the same process step, so that process steps may be saved and the production efficiency may be improved.

Exemplarily, the second conductive transfer portion 80 includes a fifth conductive transfer sub-portion 801 and a sixth conductive transfer sub-portion 802. For example, the fifth conductive transfer sub-portion 801 and the second electrode 33 are arranged in the same layer, the sixth conductive transfer sub-portion 802 and the metal conductive layer 50 are arranged in the same layer, and the second conductive transfer portion 80 is electrically connected to the first conductive transfer portion 70, so that the common cathode and the driving circuit in the base substrate may be electrically connected. In this way, while a driving effect is ensured, wires may be reduced, and a wiring space may be saved.

In order to improve stability of the light-emitting units and extend a service life of the display substrate, the display substrate may further include an encapsulation layer arranged above the LED light-emitting units. Generally, conventional LED light-emitting units are encapsulated using a stacked structure of inorganic layer-organic layer-inorganic layer. However, in order to ensure a good encapsulation effect of the encapsulation by the stacked structure of inorganic layer-organic layer-inorganic layer, the organic layer needs to be designed to be thick, and thus an overall thickness of the display substrate may be increased, which is not conducive to achieving the lightening and thinning of the display substrate.

The inventors found through research that, compared with a conventional stacked structure of inorganic layer-organic layer-inorganic layer, adopting an encapsulation structure including only stacked inorganic layers may reduce a thickness of the encapsulation layer while a good protection for the LED light-emitting units may be provided, thereby facilitating the overall thinning of the display substrate and thus the lightening and thinning of the display substrate.

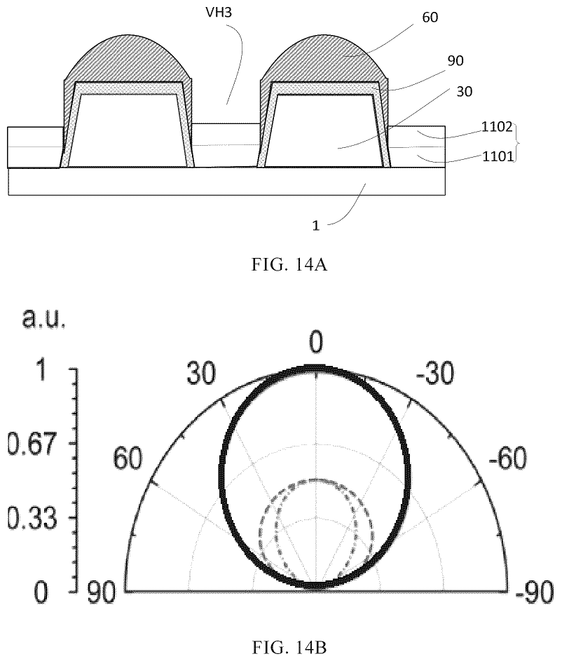

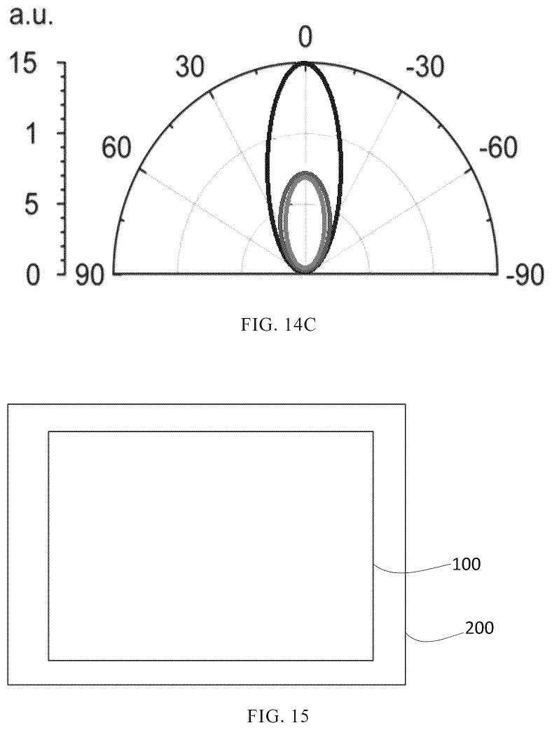

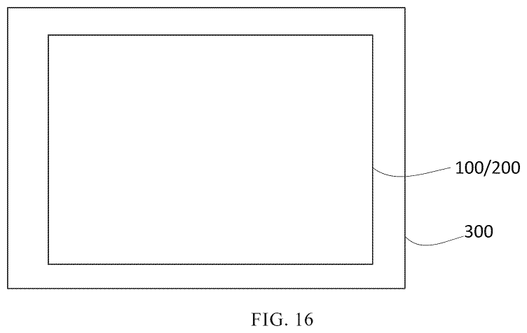

FIG. 8 shows a schematic cross-sectional view of the display substrate in FIG. 1 along line CC′, according to some exemplary embodiments of the present disclosure. FIG. 9A shows a schematic structural diagram of an inorganic encapsulation layer in a display substrate according to some exemplary embodiments of the present disclosure. FIG. 9B shows a schematic structural diagram of an inorganic encapsulation layer in a display substrate according to some other exemplary embodiments of the present disclosure. FIG. 10 shows a schematic diagram of a relationship between a gas ratio and a refractive index of an inorganic encapsulation layer according to some exemplary embodiments of the present disclosure.

Exemplarily, in some embodiments of the present disclosure, referring to FIG. 8, the display substrate further includes an inorganic encapsulation layer 90 arranged between the LED light-emitting unit 30 and the prism portion 60.

Exemplarily, the inorganic encapsulation layer 90 may include n inorganic encapsulation sub-layers that are alternately arranged, where two inorganic encapsulation sub-layers adjacent to each other among the n inorganic encapsulation sub-layers have different refractive indexes, and n is a positive integer greater than or equal to 3.

For example, in some embodiments of the present disclosure, referring to FIG. 9A, the inorganic encapsulation layer may include three inorganic encapsulation sub-layers that are alternately arranged, such as a first inorganic encapsulation sub-layer 901, a second inorganic encapsulation sub-layer 902, and a third inorganic encapsulation sub-layer 903. For example, a material of the first inorganic encapsulation sub-layer 901 may include SiCN, a material of the second inorganic encapsulation sub-layer 902 may include SiN, and a material of the third inorganic encapsulation sub-layer 903 may include SiCN.

Exemplarily, in some embodiments of the present disclosure, referring to FIG. 9B, the inorganic encapsulation layer may include five inorganic encapsulation sub-layers that are alternately arranged, such as a first inorganic encapsulation sub-layer 901, a second inorganic encapsulation sub-layer 902, a third inorganic encapsulation sub-layer 903, a fourth inorganic encapsulation sub-layer 904, and a fifth inorganic encapsulation sub-layer 905. Exemplarily, a material of the first inorganic encapsulation sub-layer 901 may include SiCN, a material of the second inorganic encapsulation sub-layer 902 may include SiN, a material of the third inorganic encapsulation sub-layer 903 may include SiCN, a material of the fourth inorganic encapsulation sub-layer 904 may include SiN, and a material of the fifth inorganic encapsulation sub-layer 905 may include SiCN.

Thicknesses of different inorganic encapsulation sub-layers may be the same or different. Exemplarily, with continued reference to FIG. 10, a thickness of the first inorganic encapsulation sub-layer 901 in the third direction D3 may be 80 nm, a thickness of the second inorganic encapsulation sub-layer 902 in the third direction D3 may be 40 nm, a thickness of the third inorganic encapsulation sub-layer 903 in the third direction D3 may be 1260 nm, a thickness of the fourth inorganic encapsulation sub-layer 904 in the third direction D3 may be 40 nm, and a thickness of the fifth inorganic encapsulation sub-layer 905 in the third direction D3 may be 80 nm. By optimizing the number and the thicknesses of the inorganic encapsulation sub-layers, a protective effect of the inorganic encapsulation layer may be further improved, thereby increasing the service life of the LED light-emitting units.

It should be noted that the number and the thicknesses of the inorganic encapsulation sub-layers in the inorganic encapsulation layer may be specifically designed according to an actual encapsulation effect, and the embodiments of the present disclosure do not specifically limit this.

For example, in some embodiments of the present disclosure, the inorganic encapsulation layer 90 may include a film layer with a high refractive index. For example, the inorganic encapsulation layer 90 may include n inorganic encapsulation sub-layers each of which has a high refractive index, and n is a positive integer greater than or equal to 3. For example, a refractive index of a material of an inorganic encapsulation sub-layer of an even number among the n inorganic encapsulation sub-layers may be greater than or equal to 1.85. For example, with continued reference to FIG. 9B, materials of the second inorganic encapsulation sub-layer 902 and the fourth inorganic encapsulation sub-layer 904 may include SiN. Referring to FIG. 10, the horizontal axis represents a relative ratio of SiH4:NH3, and the vertical axis represents a refractive index of SiN material. The two curves in FIG. 10 show the variation of the refractive index of SiN material as the relative ratio of SiH4:NH3 varies in a simulation calculation and an actual manufacturing process, respectively, and the trends of the two curves substantially coincide with each other. In the process of manufacturing SiN, a deposition power, a gas flow rate and other parameters may be adjusted, for example, the relative ratio of SiH4:NH3 may be adjusted, so that a SiN film layer with a high refractive index may be obtained. For example, the obtained SiN film layer has a refractive index of 2.0.

By designing the inorganic encapsulation layer 90 with the high refractive index, it is possible to reduce the probability of total reflection of the LED light-emitting unit when light passes through the inorganic encapsulation layer, which is conducive to improving the light extraction efficiency of the LED light-emitting unit, thereby improving the display luminance of the display substrate.

For example, in some embodiments of the present disclosure, with continued reference to FIG. 8, the prism portion 60 includes a top surface 610 away from the base substrate 1, and the top surface 610 is a cambered surface. By designing the top surface 610 of the prism portion to be the cambered surface, it is conducive to improving the light extraction efficiency of the prism portion 60, thereby improving the display luminance of the display substrate.

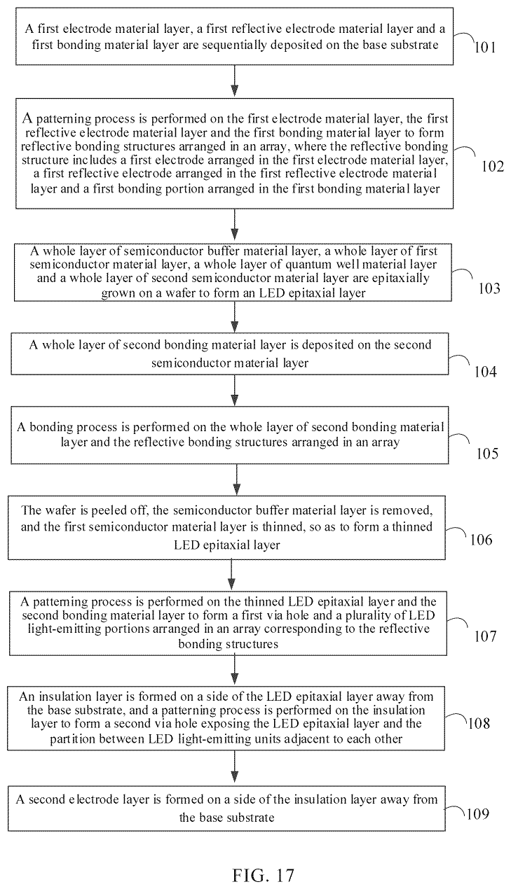

FIG. 11 shows a comparative schematic diagram of light intensities of different prism diameters at different viewing angles, according to some exemplary embodiments of the present disclosure.

For example, in some embodiments of the present disclosure, referring to FIG. 8 and FIG. 11, in a case that the prism portion 60 is added and the prism portion 60 has different diameters, different light intensities are detected at different viewing angles of the light output surface. In FIG. 11, the horizontal axis represents viewing angles having different included angles with the normal line perpendicular to the base substrate, the viewing angle parallel to the normal line being 0°, and the vertical axis represents the light intensity of the light output surface in a case that there is no prism portion and in a case that the prism portions have different diameters. After the prism portion is added, a light intensity of the light output surface at a front viewing angle is significantly increased. The front viewing angle may include a viewing angle having an included angle, with respect to the normal line perpendicular to the base substrate, in a range of ±30°. For example, referring to FIG. 11, when the diameter of the prism portion is 4 um, that is, a radius of curvature of the cambered surface of the prism portion is 2 um, a light intensity of the display substrate at the front viewing angle in the range of ±30°is increased by 200% compared to that of the display substrate without a prism portion. When the diameter of the prism portion is further increased, for example, to 4.2 um, 4.4 um or 4.6 um, the light intensity of the display substrate at the front viewing angle with the range of ±30°may be further increased, thereby achieving the high-luminance display. Light intensities of the LED light-emitting unit 30 at different viewing angles may be adjusted by optimizing the radius of curvature of the cambered surface of the prism portion. The inventors found through research that the greater the light intensity at the front viewing angle, the better the display effect. By increasing the radius of curvature of the cambered surface, the light intensity of the LED light-emitting unit at the front viewing angle may be increased, thereby improving the display effect of the display substrate. Exemplarily, the radius of curvature of the cambered surface may be greater than or equal to 2 um. For example, the radius of curvature of the cambered surface may be 2.1 um, 2.2 um, or 2.3 um.

For example, in some embodiments of the present disclosure, in the case that the encapsulation layer is added, although the encapsulation layer may provide good protection for the display substrate, the encapsulation layer may absorb part of the blue light and thus slightly reduces the luminance of the display substrate without a prism portion at the front viewing angle. Adding the prism portion on top of the encapsulation layer may focus photons, which may not only reduce the crosstalk between adjacent pixels, but also obtain a large percentage of light intensity gain at the front viewing angle.

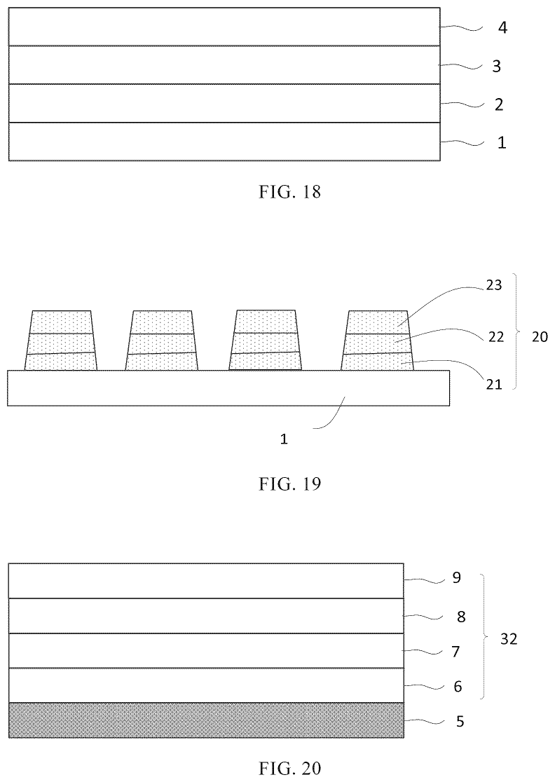

FIG. 12 shows a schematic diagram of crosstalk between adjacent pixels at different viewing angles, according to some exemplary embodiments of the present disclosure.

In the Micro LED display substrate, since a distance between adjacent pixel units is small, crosstalk is prone to occur between adjacent pixels, and the situation of crosstalk varies at different viewing angles. As the viewing angle increases, the crosstalk between pixel units tends to increase overall. The crosstalk between pixel units may affect the display effect of the display substrate and reduce user experience. By arranging a reflective layer between adjacent pixels, the crosstalk between adjacent pixel units may be reduced, thereby improving the display effect of the display substrate.

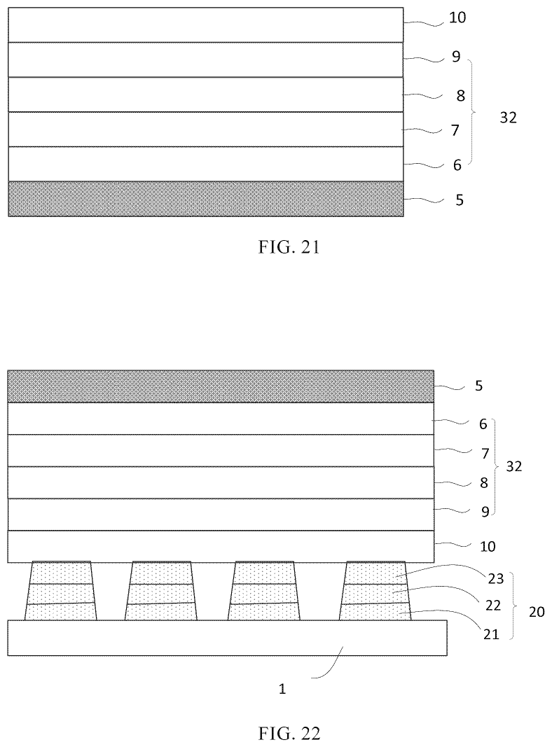

FIG. 13 shows a schematic structural diagram of a reflective layer according to some exemplary embodiments of the present disclosure.

Exemplarily, in some embodiments of the present disclosure, the display substrate further includes: a third via hole VH3 between the inorganic encapsulation layers 90 of adjacent LED light-emitting units 30; and a reflective layer 110 arranged in the third via hole VH3, where the reflective layer 110 is configured to reflect at least part of the light emitted from a side surface by the LED light-emitting unit 30.

For example, in some embodiments of the present disclosure, the reflective layer 110 may include a metal reflective layer. For example, the metal reflective layer may include a combination of one or more common metals such as Al, Ag, and Mg/Ag alloys, and the metal reflective layer may be manufactured by evaporation or magnetron sputtering. By arranging the metal reflective layer between adjacent pixels, light may be converged and the crosstalk may be reduced, thereby increasing the light intensity of the display substrate at the front viewing angle and reducing the crosstalk between pixel units adjacent to each other, so that the high-luminance and high-resolution display effect may be achieved.

Exemplarily, in some embodiments of the present disclosure, the reflective layer 110 may further include a black adhesive reflective layer. For example, an automatic dispensing machine may be used to apply the black adhesive, or a 3D printing device may be used to print the black adhesive. By arranging the black adhesive reflective layer between adjacent pixels, large-angle light from a pixel may be effectively prevented from entering an adjacent pixel, thereby reducing the crosstalk between adjacent pixel units.

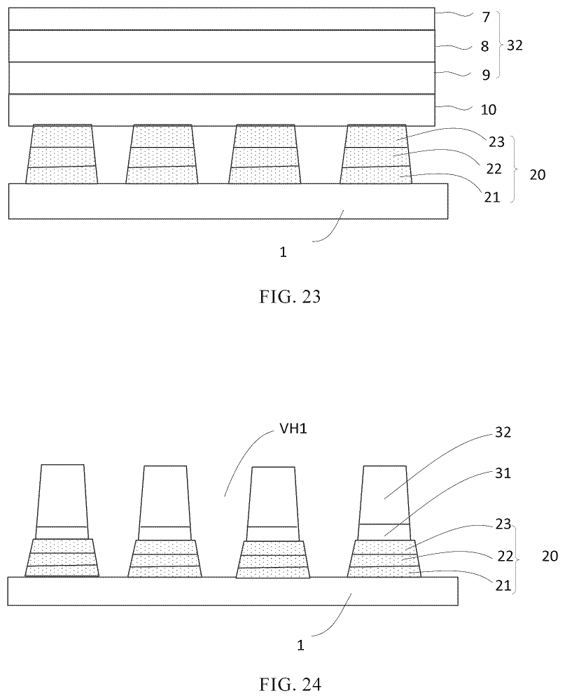

FIG. 14A shows a schematic structural diagram of a reflective layer according to some other exemplary embodiments of the present disclosure. FIG. 14B shows a schematic diagram of density distribution of photons of a display substrate without a reflective layer according to some exemplary embodiments of the present disclosure. FIG. 14C shows a schematic diagram of density distribution of photons of a display substrate provided with the reflective layer in FIG. 14A.

Exemplarily, in some embodiments of the present disclosure, the reflective layer 110 includes m inorganic reflective sub-layers that are alternately arranged, and a difference between refractive indexes of two inorganic reflective sub-layers adjacent to each other among the m inorganic reflective sub-layers is greater than or equal to 0.4, m being a positive integer greater than or equal to 2. For example, referring to FIG. 14A, the reflective layer 110 includes two inorganic reflective sub-layers, such as a first inorganic reflective sub-layer 1101 and a second inorganic reflective sub-layer 1102. Exemplarily, a material of the first inorganic reflective sub-layer 1101 may include zirconium dioxide, and a refractive index of zirconium dioxide may be 2.13. A material of the second inorganic reflective sub-layer 1102 may include zirconium, and a refractive index of zirconium may be 1.63.

In some embodiments, the reflective layer 110 may further include more inorganic reflective sub-layers. For example, the reflective layer 110 further includes a third inorganic reflective sub-layer and a fourth inorganic reflective sub-layer, a material of the third inorganic reflective sub-layer may include zirconium dioxide, and a material of the fourth inorganic reflective sub-layer may include zirconium.

Exemplarily, FIG. 14B and FIG. 14C show comparison of distribution of photons of a display substrate without a reflective layer and distribution of photons of a display substrate with an inorganic reflective layer, where the horizontal axis represents a range of viewing angles having different included angles with the normal line perpendicular to the base substrate, and the vertical axis represents a relative density of distribution of photons. By alternatively arranging more than one inorganic reflective sub-layers and forming a resonant cavity using two inorganic reflective sub-layers adjacent to each other with different refractive indexes, the density of distribution of photons of different energy states may be redistributed. For example, the distribution of photons may be changed from a loose distribution with an angle in a range of ±60° relative to the normal line perpendicular to the base substrate in FIG. 14B to a focused distribution with an angle in a range of ±30° relative to the normal line perpendicular to the base substrate in FIG. 14C, so that light of a specific wavelength which conforms to the resonant cavity mode may be emitted at a specific angle. By adding the alternatively arranged inorganic reflective sub-layers and adjusting the difference between the refractive indexes of inorganic reflective sub-layers adjacent to each other to be greater than or equal to 0.4, more light may be converged into a range of the front viewing angle which has an included angle with the normal line perpendicular to the base substrate in a range of ±30°, thereby facilitating the increase of light intensity within the range of the front viewing angle, so that the high-luminance and high-resolution display effect may be achieved.

Exemplarily, two inorganic reflective sub-layers adjacent to each other may have the same thickness or different thicknesses. The material of the inorganic reflective layer may also include a combination of two or more of GaN, SiO₂, SiN or SiON.

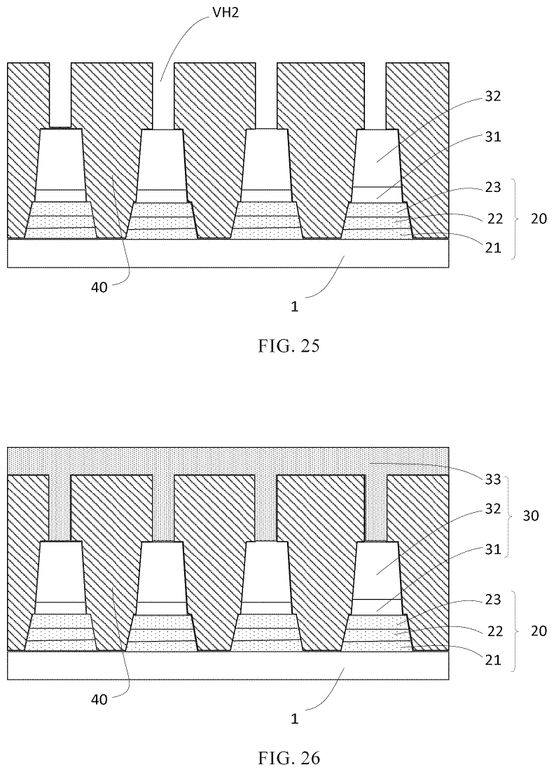

FIG. 15 shows a schematic structural diagram of a display panel according to some exemplary embodiments of the present disclosure.

Optionally, the embodiments of the present disclosure further provide a display panel. Referring to FIG. 15, the display panel 200 may include the display substrate 100 described above. It should be understood that the display panel has the same beneficial effects as the display substrate provided in the embodiments mentioned above.

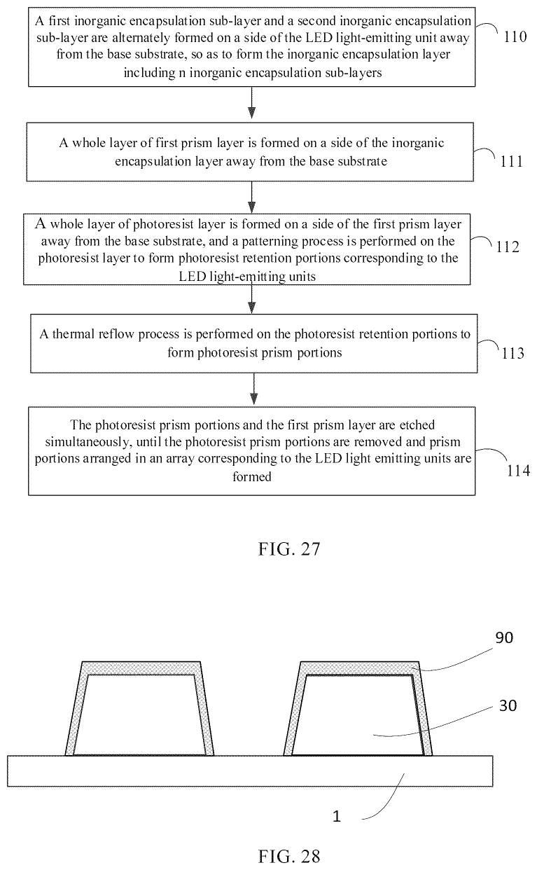

FIG. 16 shows a schematic structural diagram of a display device according to some exemplary embodiments of the present disclosure.

Optionally, the embodiments of the present disclosure further provide a display device. Referring to FIG. 16, the display device 300 may include the display substrate 100 described above or the display panel 200 described above. The display device may include, but is not limited to, an electronic paper, a mobile phone, a tablet computer, a monitor, a laptop computer, a digital photo frame, a navigator, and any other products or components with a display function. It should be understood that the display device has the same beneficial effects as the display substrate or the display panel provided in the embodiments mentioned above.

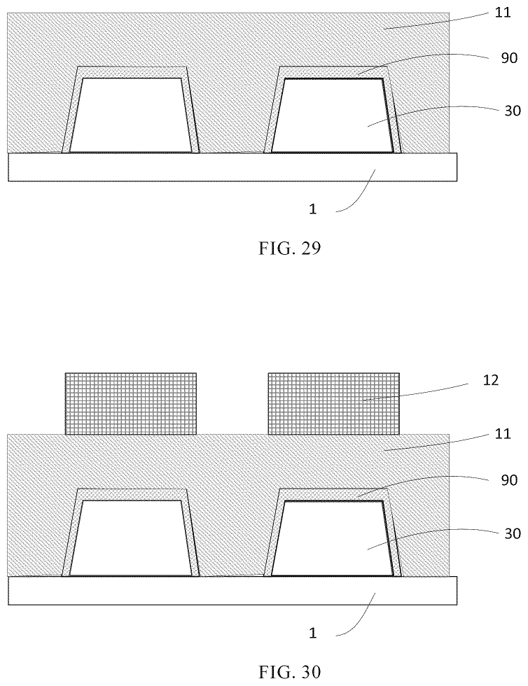

FIG. 17 shows a flow chart of a method for manufacturing a display substrate according to some exemplary embodiments of the present disclosure. FIG. 18 to FIG. 26 show partial structural schematic diagrams of the display substrate at different stages of a manufacturing process of FIG. 17, respectively.

Exemplarily, in some embodiments of the present disclosure, the method for manufacturing a display substrate includes steps S101 to S109.

In step S101, referring to FIG. 18, a first electrode material layer 2, a first reflective electrode material layer 3 and a first bonding material layer 4 are sequentially deposited on a base substrate 1.

In step S102, referring to FIG. 19, a patterning process is performed on the first electrode material layer 2, the first reflective electrode material layer 3 and the first bonding material layer 4 to form reflective bonding structures 20 arranged in an array, where the reflective bonding structure 20 includes a first electrode 21 arranged in the first electrode material layer 2, a first reflective electrode 22 arranged in the first reflective electrode material layer 3 and a first bonding portion 23 arranged in the first bonding material layer 4.

In step S103, referring to FIG. 20, a whole layer of semiconductor buffer material layer 6, a whole layer of first semiconductor material layer 7, a whole layer of quantum well material layer 8 and a whole layer of second semiconductor material layer 9 are epitaxially grown on a wafer 5, so as to form an LED epitaxial layer.

In step S104, referring to FIG. 21, a whole layer of second bonding material layer 10 is deposited on the second semiconductor material layer 9.

In step S105, referring to FIG. 22, a bonding process is performed on the whole layer of second bonding material layer 10 and the reflective bonding structures 20 arranged in an array.

In step S106, referring to FIG. 23, after the bonding process is completed, the wafer 5 is peeled off, the semiconductor buffer material layer 6 is removed, and the first semiconductor material layer 7 is thinned, so as to form the thinned LED epitaxial layer 32.

In step S107, referring to FIG. 24, a patterning process is performed on the thinned LED epitaxial layer 32 and the second bonding material layer 10 to form a first via hole VH1 and a plurality of LED light-emitting portions arranged in an array corresponding to the reflective bonding structures, where the LED light-emitting portion includes a second bonding portion 31 and an LED epitaxial layer 32.

In step S108, referring to FIG. 25, an insulation layer is formed on a side of the LED epitaxial layer away from the base substrate, and a patterning process is performed on the insulation layer, so as to form a second via hole VH2 exposing the LED epitaxial layer and a partition 40 between LED light-emitting units adjacent to each other.

In step S109, referring to FIG. 26, a second electrode layer 33 is formed on a side of the insulation layer away from the base substrate.

By forming the first bonding portions arranged in an array on the base substrate and forming a whole layer of second bonding material layer that is made of the same material as the first bonding portions on the LED epitaxial layer, the LED epitaxial layer and the base substrate may be bonded to each other without alignment, thereby improving the success rate of bonding. Furthermore, after the bonding is completed, micro-array designs of the LED epitaxial layer and the second bonding material layer may be realized through a patterning process, so as to ensure that the orthographic projection of the second bonding portion on the base substrate is located within the orthographic projection of the first bonding portion on the base substrate, forming the LED light-emitting units arranged in an array, thereby realizing the high-resolution display design.

Exemplarily, in some embodiments of the present disclosure, the method for manufacturing the display substrate further includes, after the second electrode layer is formed, forming a combination of one or more of a metal conductive layer, an inorganic encapsulation layer or a prism portion.

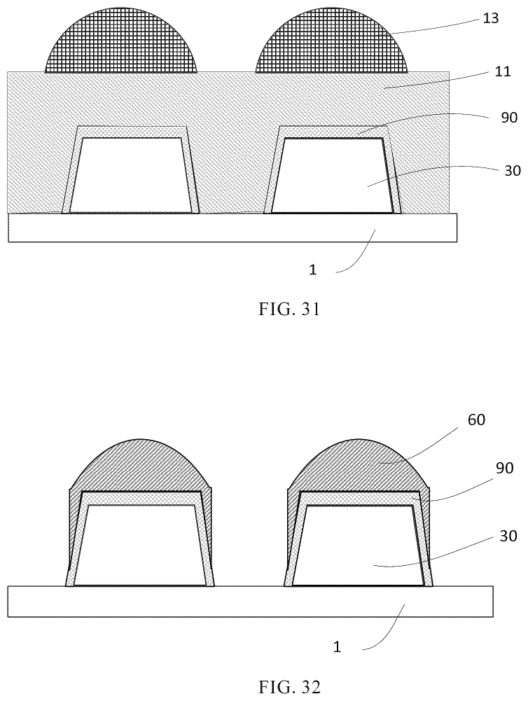

FIG. 27 shows a flow chart of forming an inorganic encapsulation layer and a prism portion according to some exemplary embodiments of the present disclosure. FIG. 28 to FIG. 32 show partial structural schematic diagrams of the display substrate at different stages of the manufacturing process of FIG. 27, respectively.

Exemplarily, in some embodiments of the present disclosure, the method for manufacturing the display substrate further includes steps S110 to S114.

In step S110, with reference to FIG. 9A, FIG. 9B and FIG. 28, a first inorganic encapsulation sub-layer 901, a second inorganic encapsulation sub-layer 902 and a third inorganic encapsulation sub-layer 903 are alternately formed on a side of the LED light-emitting unit 30 away from the base substrate, so as to form an inorganic encapsulation layer 90 including n inorganic encapsulation sub-layers, where n is a positive integer greater than or equal to 3.

In step S111, referring to FIG. 29, a whole layer of first prism layer 11 is formed on a side of the inorganic encapsulation layer 90 away from the base substrate 1.

Exemplarily, a material of the first prism layer may include a silicon nitride material with a high refractive index, which is formed using low-temperature chemical vapor deposition thin film technology. The refractive index of the silicon nitride thin film may be adjusted by adjusting parameters such as power and gas flow rates of SiH4 and NH3 during the silicon nitride deposition process. For example, by increasing a relative ratio of SiH4/NH3, more Si atoms may be supplies into the reaction chamber, that is, more Si atoms react with surplus N atoms, so that a concentration of the reaction precursor is increased, and the gas may fully react on a surface of the base substrate to form a dense thin film, thereby increasing the refractive index of the thin film.

In step S112, referring to FIG. 30, a whole layer of photoresist layer is formed on a side of the first prism layer away from the base substrate, and a patterning process is performed on the photoresist layer, so as to form photoresist retention portions 12 corresponding to the LED light-emitting units 30.

In step S113, referring to FIG. 31, a thermal reflowing process is performed on the photoresist retention portions 12 to form photoresist prism portions 13.

In step S114, referring to FIG. 32, the photoresist prism portions 13 and the first prism layer 11 are etched simultaneously, until the photoresist prism portions 13 are removed, so as to form prism portions 60 arranged in an array corresponding to the LED light emitting units.

By adding the prism portion, the light intensity of the display substrate at the front viewing angle may be improved and the crosstalk between pixels adjacent to each other may be reduced, so that the high-luminance and high-resolution display effect may be achieved.

Exemplarily, in some embodiments of the present disclosure, the larger a radius of the cambered surface of the prism portion is, the more the light intensity at the front viewing angle is improved, and the higher the display luminance of the display substrate is.

Although some embodiments of the general inventive concept of the present disclosure have been shown and described, it will be understood by those of ordinary skill in the art that changes may be made to these embodiments without departing from the principles and spirit of the general inventive concept of the present disclosure, and the scope of the present disclosure is defined by the claims and their equivalents.

1. A display substrate, comprising:
a base substrate, comprising a display area and a peripheral area, the peripheral area at least partially surrounding the display area; and
a plurality of pixel units arranged in the display area of the base substrate, the plurality of pixel units being arranged in an array in the display area along a first direction and a second direction, at least one of the pixel units comprising a reflective bonding structure and an LED light-emitting unit, and the first direction intersecting with the second direction,
wherein the reflective bonding structure comprises: a first electrode arranged on the base substrate; a first reflective electrode arranged on a side of the first electrode away from the base substrate; and a first bonding portion arranged on a side of the first reflective electrode away from the base substrate; and
wherein the LED light-emitting unit comprises:
a second bonding portion arranged on a side of the first bonding portion away from the base substrate;
an LED epitaxial layer arranged on a side of the second bonding portion away from the base substrate; and
a second electrode arranged on a side of the LED epitaxial layer away from the base substrate,
wherein an orthographic projection of the second bonding portion on the base substrate is located within an orthographic projection of the first bonding portion on the base substrate; and
wherein the first bonding portion and the second bonding portion comprise a same material.

2. The display substrate of claim 1, wherein the first bonding portion and the second bonding portion comprise the same material selected from ITO or IZO.

3. The display substrate of claim 2, wherein:
the first bonding portion comprises a first slope angle ranging from 70° to 85°; and/or
the second bonding portion comprises a second slope angle ranging from 70° to 85°.

4. The display substrate of claim 3, wherein:
a material of the first electrode is one of ITO or IZO; and/or
a material of the first reflective electrode is silver.

5. The display substrate of claim 1, further comprising a partition between pixel units adjacent to each other, wherein the partition covers at least a part of a surface of the LED epitaxial layer away from the base substrate, a sidewall of the reflective bonding structure, and a sidewall of the LED light-emitting unit.

6. The display substrate of claim 5, wherein:
the partition has a first thickness in a third direction, the third direction being perpendicular to each of the first direction and the second direction;
the reflective bonding structure has a second thickness in the third direction;
the second bonding portion has a third thickness in the third direction;
the LED epitaxial layer has a fourth thickness in the third direction; and
the first thickness is greater than a sum of the second thickness, the third thickness and the fourth thickness.

7. The display substrate of claim 5, wherein:
the LED epitaxial layer comprises:
a second semiconductor layer arranged on the side of the second bonding portion away from the base substrate;
a quantum well layer arranged on a side of the second semiconductor layer away from the base substrate; and
a first semiconductor layer arranged on a side of the quantum well layer away from the base substrate; and
the partition comprises a hole, exposing at least a part of a surface of the first semiconductor layer away from the base substrate.

8. The display substrate of claim 5, wherein the second electrode comprises a main body portion and a second conductive connection portion, an orthographic projection of the second conductive connection portion on the base substrate coincides with an orthographic projection of the partition on the base substrate, and second electrodes of two pixel units adjacent to each other are electrically connected via the second conductive connection portion, and
wherein the main body portion has a fifth thickness in a third direction, and the second conductive connection portion has a sixth thickness in the third direction, the fifth thickness being greater than the sixth thickness.

9. The display substrate according to claim 8, further comprising a metal conductive layer arranged on a side of the second electrode away from the base substrate,
wherein an orthographic projection of the metal conductive layer on the base substrate is located within the orthographic projection of the second conductive connection portion on the base substrate; and
wherein the metal conductive layer comprises a plurality of first conductive sub-portions arranged along the first direction and a plurality of second conductive sub-portions arranged along the second direction, and the plurality of first conductive sub-portions and the plurality of second conductive sub-portions are electrically connected to each other.

10. The display substrate of claim 9, wherein the metal conductive layer comprises:
a first metal conductive sub-layer arranged on the side of the second electrode away from the base substrate;
a second metal conductive sub-layer arranged on a side of the first metal conductive sub-layer away from the base substrate; and
a third metal conductive sub-layer arranged on a side of the second metal conductive sub-layer away from the base substrate,
wherein an orthographic projection of the second metal conductive sub-layer on the base substrate is located within an orthographic projection of the first metal conductive sub-layer on the base substrate; and
wherein an orthographic projection of the third metal conductive sub-layer on the base substrate is located within the orthographic projection of the second metal conductive sub-layer on the base substrate.

11. The display substrate of claim 1, further comprising a prism portion arranged on a side of the second electrode away from the base substrate,
wherein an orthographic projection of the prism portion on the base substrate at least partially overlaps with an orthographic projection of the LED epitaxial layer on the base substrate.

12. The display substrate according to claim 11, further comprising a first conductive transfer portion and a second conductive transfer portion arranged in the peripheral area, the first conductive transfer portion being electrically connected to the second conductive transfer portion,
wherein the first conductive transfer portion comprises a first conductive transfer sub-portion, a second conductive transfer sub-portion, a third conductive transfer sub-portion, and a fourth conductive transfer sub-portion, wherein:
the first conductive transfer sub-portion and the first electrode are arranged in a same layer;
the second conductive transfer sub-portion and the first reflective electrode are arranged in a same layer;
the third conductive transfer sub-portion and the first bonding portion are arranged in a same layer; and
the fourth conductive transfer sub-portion and the second bonding portion are arranged in a same layer; and
wherein the second conductive transfer portion comprises a fifth conductive transfer sub-portion and a sixth conductive transfer sub-portion, wherein:
the fifth conductive transfer sub-portion and the second electrode are arranged in a same layer; and
the sixth conductive transfer sub-portion and the metal conductive layer are arranged in a same layer.

13. The display substrate of claim 11, further comprising an inorganic encapsulation layer arranged between the LED light-emitting unit and the prism portion.

14. The display substrate of claim 13, wherein the inorganic encapsulation layer comprises n inorganic encapsulation sub-layers that are alternately arranged,
wherein two inorganic encapsulation sub-layers adjacent to each other among the n inorganic encapsulation sub-layers have different refractive indexes, n being a positive integer greater than or equal to 3; and
wherein a refractive index of a material of an inorganic encapsulation sub-layer of an even number among the n inorganic encapsulation sub-layers is greater than or equal to 1.85.

15. (canceled)

16. The display substrate of claim 11, wherein the prism portion comprises a top surface away from the base substrate, the top surface being a cambered surface; and
wherein a radius of curvature of the cambered surface is greater than or equal to 2 um.

17. (canceled)

18. The display substrate of claim 13, further comprising:
a third via hole between inorganic encapsulation layers of LED light-emitting units adjacent to each other; and
a reflective layer arranged in the third via hole, wherein the reflective layer is configured to reflect at least part of light emitted from a side surface by the LED light-emitting until;
wherein the reflective layer comprises m inorganic reflective sub-layers that are alternately arranged, and a difference between refractive indexes of two inorganic reflective sub-layers adjacent to each other among the m inorganic reflective sub-layers is greater than or equal to 0.4, m being a positive integer greater than or equal to 2; and
wherein the reflective layer comprises a metal reflective layer or a black adhesive reflective layer.

19. (canceled)

20. (canceled)

21. A display panel, comprising the display substrate of claim 1.

22. A display device, comprising the display substrate of claim 1.

23. A method for manufacturing a display substrate, comprising:
sequentially depositing a first electrode material layer, a first reflective electrode material layer and a first bonding material layer on a base substrate;
performing a patterning process on the first electrode material layer, the first reflective electrode material layer and the first bonding material layer to form reflective bonding structures arranged in an array, wherein the reflective bonding structure comprises a first electrode arranged in the first electrode material layer, a first reflective electrode arranged in the first reflective electrode material layer, and a first bonding portion arranged in the first bonding material layer;
epitaxially growing a whole layer of semiconductor buffer material layer, a whole layer of first semiconductor material layer, a whole layer of quantum well material layer and a whole layer of second semiconductor material layer on a wafer, so as to form an LED epitaxial layer;
depositing a whole layer of second bonding material layer on the second semiconductor material layer;
performing a bonding process on the whole layer of second bonding material layer and the reflective bonding structures arranged in the array;
after the bonding process is completed, peeling off the wafer, removing the semiconductor buffer material layer, and thinning the first semiconductor material layer, so as to form a thinned LED epitaxial layer;
performing a patterning process on the thinned LED epitaxial layer and the second bonding material layer, so as to form a first via hole and a plurality of LED light-emitting portions arranged in an array corresponding to the reflective bonding structures;
forming an insulation layer on a side of the LED epitaxial layer away from the base substrate, and performing a patterning process on the insulation layer, so as to form a second via hole exposing the LED epitaxial layer and a partition between LED light-emitting units adjacent to each other; and
forming a second electrode layer on a side of the insulation layer away from the base substrate.

24. The method of claim 23, further comprising:
alternately forming a first inorganic encapsulation sub-layer and a second inorganic encapsulation sub-layer on a side of the LED light-emitting units away from the base substrate, so as to form an inorganic encapsulation layer comprising n inorganic encapsulation sub-layers, n being a positive integer greater than or equal to 3;
forming a whole layer of first prism layer on a side of the inorganic encapsulation layer away from the base substrate;
forming a whole layer of photoresist layer on a side of the first prism layer away From the base substrate, and performing a patterning process on the photoresist layer, so as to form photoresist retention portions respectively corresponding to the LED light-emitting units;
performing a thermal reflowing process on the photoresist retention portions to form photoresist prism portions; and
simultaneously etching the photoresist prism portions and the first prism layer until the photoresist prism portions are removed, so as to form prism portions arranged in an array and respectively corresponding to the LED light emitting units.
